(19) United States
(12) Patent Application Publication
(10) Pub. No.: US 2025/0151206 A1
(43) Pub. Date: May 8, 2025

(54) CREATING A SOLDER BARRIER BY CHANGING A MATERIAL PROPERTY OF A TRACE ON A PRINTED CIRCUIT BOARD

(71) Applicant: Sandsik Technologies, Inc., Milpitas, CA (US)

(72) Inventor: John Patrick Burke, San Jose, CA (US)

(21) Appl. No.: 18/504,408

(22) Filed: Nov. 8, 2023

(51) Int. Cl. H05K 3/34

(52) U.S. Cl. CPC H05K 3/3452; H05K 3/341; H05K 2203/0465

(57) ABSTRACT

A printed circuit board (PCB) includes a connection area and a trace extending from the connection area. A solder barrier is provided on at least a portion of the trace. The solder barrier is used in lieu of a solder mask. The solder barrier is formed by a laser oxidation process or a laser ablation process, which alters a material property of the trace. Altering the material property of the trace causes the altered portion of the trace to be non-solderable, but does not negatively impact the speed or reliability of signal transmission along the trace.

### BACKGROUND

A solder mask is a thin protective layer that is applied to a surface of a printed circuit board (PCB). One purpose of the solder mask is to prevent solder from flowing into unintended areas on the PCB. For example, some PCBs include a number of traces placed on the surface of the PCB. A thin solder mask strip is typically placed on the trace to prevent solder from flowing out of the solder pad and onto the trace.

However, as traces get more narrow and as the pitch between the traces get smaller, it is increasingly difficult to prevent solder flow out. Additionally, due to the dielectric constant of a solder mask, placing a solder mask on or over the traces introduces dielectric loss, which may cause signal degradation or interruption.

Accordingly, it would be beneficial to eliminate the need for solder masks on traces while still preventing solder from flowing out of a solder pad and onto the trace.

### SUMMARY

The present disclosure describes creating a solder barrier for a printed circuit board (PCB) without using a solder mask. In an example, the solder barrier is created or formed on a connection area (e.g., a solder pad) of the PCB and/or on a trace of the PCB by changing a material property of the connection area and/or the trace. For example, a portion of the connection area and/or the trace may undergo a laser ablation process or a laser oxidation process which compromises a finish on the connection area and/or the trace. The compromised area is non-solderable, which prevents solder from migrating from the connection area and onto the trace.

Accordingly, examples of the present disclosure describe a PCB that includes a connection area for receiving an electronic component. A trace extends from the connection area. A solder barrier is provided on at least one of a portion of the connection area and a portion of the trace. In an example, the solder barrier is formed by changing a material property of the at least one of the portion of the connection area and the portion of the trace.

The present disclosure also describes a PCB that includes an attachment means provided on a surface of the PCB. In an example, the attachment means receives an electronic component. A signal transmission means extends from the attachment means. A solder barrier means is provided on at least one of a portion of the attachment means and a portion of the signal transmission means. In an example, the solder barrier means is formed by changing a property of the at least one of the portion of the attachment means and the portion of the signal transmission means.

In yet other examples, a method is described. The method includes forming a trace and a solder pad on a top surface of a PCB. A solder barrier is formed by altering a material property of a portion of at least one of the trace and the solder pad. In an example, the solder barrier is used in lieu of a solder mask on the at least one of the trace and the solder pad.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates an integrated circuit having an electronic component surface mounted to a PCB according to an example.

FIG. 1B illustrates the integrated circuit of FIG. 1A when the solder mask is omitted according to an example.

FIG. 2 illustrates how a solder barrier is created on a trace of a PCB according to an example.

FIG. 3 illustrates an integrated circuit having a solder barrier provided proximate to a connection area on a PCB according to an example.

FIG. 4 illustrates a method for creating a solder barrier on a PCB according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

A solder mask is a protective layer or coating that is used to insulate and shield copper traces on a printed circuit board (PCB). For example, a solder mask provides protection against oxidation, helps prevent solder from flowing on or over the traces and also helps prevent solder bridges from forming between closely spaced traces and/or solder pads.

In some implementations, such as high-speed integrated circuits (or high-speed PCB applications), high-speed traces and associated solder pads are placed on the surface of the PCB. A thin solder mask strip is placed on each high-speed trace to prevent solder from flowing out of the solder pad and onto the high-speed trace. However, due to the dielectric constant of solder masks, placing solder masks on or over the high-speed traces introduces dielectric loss to the high-speed traces, which negatively impacts the overall performance of the integrated circuit.

In order to address the above, the present disclosure describes creating a solder barrier for a PCB without using a solder mask. In an example, the solder barrier is created or formed on a connection area (e.g., a solder pad) of the PCB and/or on a trace of the PCB by changing or altering a material property of the connection area and/or the trace. For example, a laser is used to compromise a finish on the connection area and/or the trace. In an example and depending on the finish, the laser may either ablate or oxidize at least a portion of the trace and/or at least a portion of the connection area. The compromised area is non-solderable, which prevents solder from migrating from the connection area and onto/over the trace.

Accordingly, the present application provides many technical benefits including, but not limited to, preventing solder flow out without using a solder mask, removing the need for solder masks on traces and/or connection areas and reducing or eliminating dielectric loss which improves signal transmission along the traces.

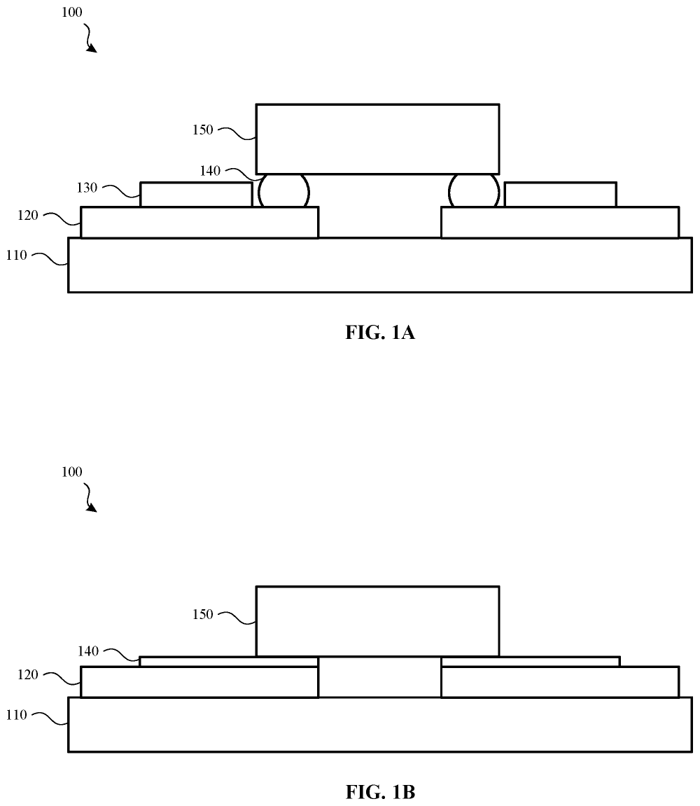

These and other examples will be shown and described in greater detail with respect to FIG. 1A-FIG. 4.

FIG. 1A illustrates an integrated circuit 100 having an electronic component 150 surface mounted to a PCB 110 according to an example. In an example, a solder pad 120 and an associated trace is provided on a top surface of the PCB 110. Solder 140 (in the form of solder balls) is used to surface mount the electronic component 150 to each solder pad 120. Additionally, a solder mask 130 is provided on each solder pad 120 and/or the associated trace.

In an example, the solder mask 130 prevents solder flow out when the electronic component 150 is surface mounted on the PCB 110. For example, when solder 140 is used to surface mount the electronic component 150 to the solder pads 120 of the PCB 110, the solder mask 130 prevents the solder 140 from moving or flowing out of a joint area (e.g., the area on the solder pad 120 at which the electronic component 150 is coupled to the solder pads 120) on the PCB 110.

While the solder mask 130 prevents solder flow out, as previously explained, a dielectric constant of the solder mask 130 introduces dielectric loss to the traces of the integrated circuit 100. Dielectric loss negatively impacts the transmission speed of signals to and from the electronic component 150 and along the trace.

FIG. 1B illustrates the integrated circuit 100 of FIG. 1A when the solder mask is omitted according to an example. Like the example shown in FIG. 1A, a solder pad 120 and an associated trace is provided on a top surface of the PCB 110. Solder 140 is used to surface mount the electronic component 150 to each solder pad 120. However, because the solder mask (e.g., the solder mask 130 (FIG. 1A)) is omitted, the solder 140 flows out of the joint area on each solder pad 120.

While the omission of the solder mask may eliminate the dielectric loss and increase the performance of the integrated circuit 100, solder flow out causes the electronic component 150 to collapse onto the solder pad 120. This creates a low-reliability joint, which may negatively impact the overall performance of the integrated circuit 100.

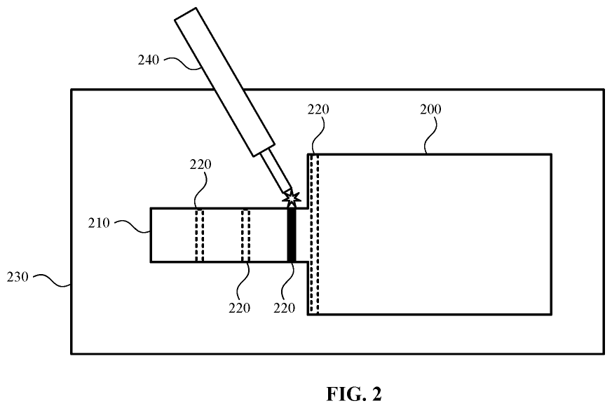

FIG. 2 illustrates how a solder barrier 220 is created on a trace 210 of a PCB 230 according to an example. In an example, the solder barrier 220 is created during a PCB fabrication process. In another example, the solder barrier 220 is created during an integrated circuit fabrication process. As will be explained, the solder barrier 220 is used in lieu of a solder mask, thereby improving the speed and reliability of signals that are transmitted along the various traces of the PCB 230.

The PCB 230 includes a connection area 200 and a trace 210 extending from, or otherwise associated with, the connection area 200. In an example, the connection area 200 is a solder pad. Although a solder pad is specifically mentioned, the connection area 200 is any connection point or area on the PCB 230 that receives or is otherwise coupleable to an electronic component.

In an example, the trace 210 is a high-speed trace provided on the surface of the PCB 230. Although a high-speed trace is specifically mentioned, the trace 210 may be any type of signal transmission element that enables signals to be received and/or transmitted between various electronic components that are coupled to or mounted on the PCB 230.

Additionally, the trace 210, the PCB 230 and/or the connection area 200 may have or otherwise be associated with a finish. For example, the finish of the trace 210, the PCB 230 and/or the connection area 200 may be an organic surface protectant (OSP), immersion silver, immersion tin, electroless nickel immersion gold (ENIG), electroless nickel electroless palladium immersion gold (ENEPIG), or copper. Although specific finished are mentioned, other finishes may be used.

Each of the finishes listed above may have very thin solderable surfaces, a surface that is sensitive to oxidation, or both. In order to create the solder barrier 220, a laser 240 is used to change a material property of at least a portion of the trace 210 (or the PCB 230 and/or the connection area 200). In an example, changing the material property of at least the portion of the trace 210 (and/or at least a portion of the connection area 200) causes the at least the portion of the trace 210 to be non-solderable, thereby preventing solder from flowing on or over the solder barrier 220.

For example, copper, OSP, immersion tin and immersion silver (with or without OSP) when oxidized by the laser 240, is a non-solderable surface. As such, when the trace 210, the connection area 200 and/or the PCB 230 (or portions of the trace 210, the connection area 200 and/or the PCB 230) have one or more of these finishes, the laser 240 forms an oxidized strip or stripe on one or more portions of the trace 210, the connection area 200 and/or the PCB 230. Because solder cannot flow onto or over the oxidized stripe, the solder barrier 220 is formed.

In another example, ENIG, ENEPIG, and immersion silver, when ablated by the laser 240, have a non-solderable surface. As such, when the trace 210, the connection area 200 and/or the PCB 230 (or portions of the trace 210, the connection area 200 and/or the PCB 230) have one or more of these finishes, the laser 240 ablates the surface on one or more portions of the trace 210, the connection area 200 and/or the PCB 230 to form the solder barrier 220.

In an example, the laser 240 is a low input power laser and the beam has a width of twenty-five microns. Although a specific power and width are mentioned, a laser 240 having a higher input power with a diffused beam may be used to create the solder barrier 220.

In an example, the solder barrier 220 is formed on the trace 210 proximate to, or adjacent to, the connection area 200. In another example, the solder barrier 220 may be formed on any location on the trace 210.

Although FIG. 2 illustrates that solder barrier 220 is formed on the trace 210, the solder barrier 220 may be formed on the connection area 200 (represented by the dashed lines). For example, the solder barrier 220 may be formed on the connection area 200 proximate to the trace 210. In another example, the solder barrier 220 may be formed around the perimeter of the connection area 200 or at least partially around the perimeter of the connection area 200. In yet another example, multiple solder barriers 220 may be formed on the trace 210 and/or on the connection area 200. For example, three different solder barriers 220 may be formed on different locations on the trace 210 (represented by the solid line and the dashed lines).

Using the laser 240 create the solder barrier 220 may be more efficient in terms of time and cost when compared with a conventional solder mask application process. Additionally, the laser 240 may be more accurate in terms of solder barrier placement and width when compared with the conventional solder mask application process.

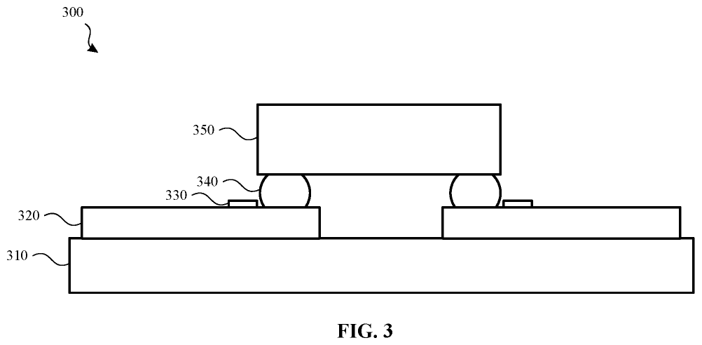

FIG. 3 illustrates an integrated circuit 300 having a solder barrier 330 provided proximate to a connection area 320 on a PCB 310 according to an example. In this example, the integrated circuit 300 includes a PCB 310 and a connection area 320 provided on a top surface of the PCB 310. An electronic component 350 is coupled to the connection area 320 using one or more solder balls 340. Although solder balls 340 are specifically mentioned, other connection methods may be used to couple the electronic component 350 to the connection area 320.

In an example, the connection area 320 is a solder pad. Although a solder pad is specifically mentioned, the connection area 320 may be any type of connection area that receives an electronic component 350. A trace (e.g., the trace 210 (FIG. 2)) extends from, or is otherwise associated with, the connection area 320.

The solder barrier 330 is formed on at least a portion of the connection area 320 and/or on at least a portion of the trace that extends from the connection area 320. In an example, the solder barrier 330 is formed by changing or altering a material property of the portion of the trace and/or the connection area. For example, a laser is used to change the material property of the portion of the trace and/or the connection area 320 such that the portion of the trace and/or the portion of the connection area 320 is non-solderable.

For example and depending on the finish of the trace and/or the connection area 320, a laser is used to either oxidize or ablate at least a portion of the trace and/or the connection area 320 which forms the solder barrier 330. As shown in FIG. 3, the solder barrier 330 prevents the solder 340 from flowing out of the joint area of the connection area 320 and onto the trace.

As previously explained, the solder barrier 330 is used in lieu of a solder mask. Additionally, unlike a solder mask which can interrupt and/or degrade a signal that is transmitted along with trace, the oxidized/ablated portion of the trace does not negatively impact the signal.

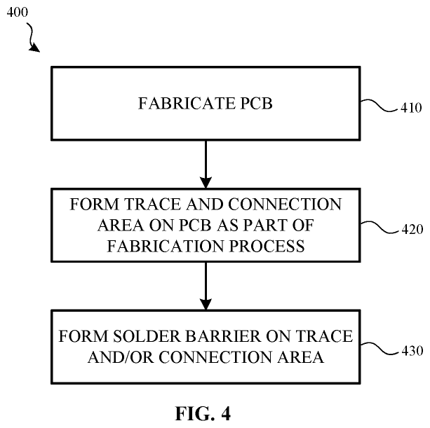

FIG. 4 illustrates a method 400 for creating a solder barrier according to an example. In an example, the method 400, or portions of the method 400, may be performed as part of a PCB fabrication process and/or integrated circuit fabrication process. Additionally, the method 400, or portions of the method 400 may be used to create the PCB 230 shown and described with respect to FIG. 2 and/or the integrated circuit 300 shown and described with respect to FIG. 3.

Method 400 begins when a PCB is fabricated (410). In an example, various fabrication techniques may be used to fabricate the PCB.

During the fabrication process, one or more traces and connection areas are formed (420) on the PCB. For example, the one or more traces may be high-speed traces formed on a surface of the PCB. Additionally, each of the one or more traces extend from one or more connection areas. In an example, the connection area is a solder pad that receives an electronic component during an integrated circuit fabrication process.

When the trace and/or a connection area is formed on the PCB, a solder barrier is formed (430) on at least a portion of the trace and/or the connection area. In an example, a laser oxidizes or ablates the portion of the trace and/or connection area. The laser ablation process or the laser oxidation process changes a material property of the trace and/or the connection area such that the area is non-solderable.

For example, if the trace and/or the connection area has a first type of finish (e.g., copper, OSP, immersion tin or immersion silver (with or without OSP)) a laser oxidation process is used to form the solder barrier. However, if the trace and/or the connection area has a second type of finish (e.g., ENIG, ENEPIG, or immersion silver), a laser ablation process is used to form the solder barrier.

Based on the above, examples of the present disclosure describe a printed circuit board (PCB), comprising: a connection area for receiving an electronic component; a trace extending from the connection area; and a solder barrier provided on at least one of a portion of the connection area and a portion of the trace, the solder barrier being formed by changing a material property of the at least one of the portion of the connection area and the portion of the trace. In an example, the solder barrier is formed by a laser ablation process. In an example, the solder barrier is formed by a laser oxidation process. In an example, the trace is a high-speed trace. In an example, when the solder barrier is provided on the portion of the trace, the portion of the trace on which the solder barrier is provided is proximate to the connection area. In an example, the connection area is a solder pad. In an example, a finish of at least one of the connection area and the trace is selected from a group, comprising: organic surface protectant (OSP); immersion silver; immersion tin; electroless nickel immersion gold (ENIG); electroless nickel electroless palladium immersion gold (ENEPIG); and copper.

Other examples describe a printed circuit board (PCB), comprising: an attachment means provided on a surface of the PCB, the attachment means for receiving an electronic component; a signal transmission means extending from the attachment means; and a solder barrier means provided on at least one of a portion of the attachment means and a portion of the signaling means, the solder barrier means being formed by changing a property of the at least one of the portion of the attachment means and the portion of the signal transmission means. In an example, the solder barrier means is formed by a laser ablation process. In an example, the solder barrier means is formed by a laser oxidation process. In an example, the signal transmission means is a high-speed trace provided on a surface of the PCB. In an example, when the solder barrier means is provided on the portion of the signal transmission means, the portion of the signal transmission means on which the solder barrier is provided is proximate to the attachment means. In an example, the attachment means is a solder pad. In an example, the solder barrier means is formed on portion of a perimeter of the attachment means. In an example, a finish of at least one of the attachments means and the signal transmission means is selected from a group, comprising: organic surface protectant (OSP); immersion silver; immersion tin; electroless nickel immersion gold (ENIG); electroless nickel electroless palladium immersion gold (ENEPIG); and copper.

Other examples describe a method, comprising: forming a trace and a solder pad on a top surface of a printed circuit board (PCB); and forming a solder barrier by altering a material property of a portion of at least one of the trace and the solder pad, the solder barrier being used in lieu of a solder mask on the at least one of the trace and the solder pad. In an example, the solder barrier is formed using a laser ablation process. In an example, the solder barrier is formed by a laser oxidation process. In an example, the solder barrier is formed on the trace proximate to the solder pad. In an example, a finish of at least one of the attachments means and the signal transmission means is selected from a group, comprising: organic surface protectant (OSP); immersion silver; immersion tin; electroless nickel immersion gold (ENIG); electroless nickel electroless palladium immersion gold (ENEPIG); and copper.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A printed circuit board (PCB), comprising:
a connection area for receiving an electronic component;
a trace extending from the connection area; and
a solder barrier provided on at least one of a portion of the connection area and a portion of the trace, the solder barrier being formed by changing a material property of the at least one of the portion of the connection area and the portion of the trace.

2. The PCB of claim 1, wherein the solder barrier is formed by a laser ablation process.

3. The PCB of claim 1, wherein the solder barrier is formed by a laser oxidation process.

4. The PCB of claim 1, wherein the trace is a high-speed trace.

5. The PCB of claim 1, wherein when the solder barrier is provided on the portion of the trace, the portion of the trace on which the solder barrier is provided is proximate to the connection area.

6. The PCB of claim 1, wherein the connection area is a solder pad.

7. The PCB of claim 1, wherein a finish of at least one of the connection area and the trace is selected from a group, comprising:
organic surface protectant (OSP);
immersion silver;
immersion tin;
electroless nickel immersion gold (ENIG);
electroless nickel electroless palladium immersion gold (ENEPIG); and
copper.

8. A printed circuit board (PCB), comprising:
an attachment means provided on a surface of the PCB, the attachment means for receiving an electronic component;
a signal transmission means extending from the attachment means; and
a solder barrier means provided on at least one of a portion of the attachment means and a portion of the signaling means, the solder barrier means being formed by changing a property of the at least one of the portion of the attachment means and the portion of the signal transmission means.

9. The PCB of claim 8, wherein the solder barrier means is formed by a laser ablation process.

10. The PCB of claim 8, wherein the solder barrier means is formed by a laser oxidation process.

11. The PCB of claim 8, wherein the signal transmission means is a high-speed trace provided on a surface of the PCB.

12. The PCB of claim 8, wherein when the solder barrier means is provided on the portion of the signal transmission means, the portion of the signal transmission means on which the solder barrier is provided is proximate to the attachment means.

13. The PCB of claim 8, wherein the attachment means is a solder pad.

14. The PCB of claim 8, wherein the solder barrier means is formed on portion of a perimeter of the attachment means.

15. The PCB of claim 8, wherein a finish of at least one of the attachments means and the signal transmission means is selected from a group, comprising:
organic surface protectant (OSP);
immersion silver;
immersion tin;
electroless nickel immersion gold (ENIG);
electroless nickel electroless palladium immersion gold (ENEPIG); and
copper.

16. A method, comprising:
forming a trace and a solder pad on a top surface of a printed circuit board (PCB); and
forming a solder barrier by altering a material property of a portion of at least one of the trace and the solder pad, the solder barrier being used in lieu of a solder mask on the at least one of the trace and the solder pad.

17. The method of claim 16, wherein the solder barrier is formed using a laser ablation process.

18. The method of claim 16, wherein the solder barrier is formed by a laser oxidation process.

19. The method of claim 18, wherein the solder barrier is formed on the trace proximate to the solder pad.

20. The method of claim 16, wherein a finish of at least one of the attachments means and the signal transmission means is selected from a group, comprising:
organic surface protectant (OSP);
immersion silver;
immersion tin;
electroless nickel immersion gold (ENIG);
electroless nickel electroless palladium immersion gold (ENEPIG); and
copper.
